(19) United States
(12) Patent Application Publication
(10) Pub. No.: US 2025/0380434 A1
(43) Pub. Date: Dec. 11, 2025

(54) SEMICONDUCTOR PACKAGE

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 18/971,087

(22) Filed: Dec. 6, 2024

(30) Foreign Application Priority Data
Jun. 7, 2024 (KR) 10-2024-0074494

(51) Int. Cl. H10D 1/68; H01L 23/498; H01L 25/07

(52) U.S. Cl. CPC H10D 1/692; H01L 23/49816; H01L 23/49838; H01L 25/072; H01L 23/49866

(57) ABSTRACT

Some example embodiments are directed to a semiconductor package including a first redistribution layer including first wiring, a semiconductor die on a surface of the first redistribution layer, and a capacitor on the surface of the first redistribution layer and spaced apart from the semiconductor die in a direction parallel to the surface of the first redistribution layer. The capacitor is electrically connected to the first wiring, and includes an insulation layer, a first electrode layer, a dielectric layer, and a second electrode layer that are stacked in a sequential order in a direction perpendicular to the first redistribution layer. The semiconductor package also includes a post on the capacitor and extending in a direction perpendicular to the surface of the first redistribution layer and electrically connected to the first redistribution layer.

### CROSS-REFERENCE TO RELATED APPLICATION

This application claims priority under 35 U.S.C. § 119 to Korean Patent Application No. 10-2024-0074494, filed on Jun. 7, 2024, in the Korean Intellectual Property Office, the entire disclosure of which is incorporated herein by reference.

### BACKGROUND

Example embodiments relate to a semiconductor package.

With miniaturization of a mobile device, a thickness of a semiconductor package is also reduced. However, it is challenging to reduce a thickness of a semiconductor packaging because of a structure and/or arrangement of a capacitor included in the semiconductor package.

### SUMMARY

According to some example embodiments, a semiconductor package may include a first redistribution layer having first wiring, a semiconductor die on a surface of the first redistribution layer, and a capacitor on the surface of the first redistribution layer and spaced apart from the semiconductor die in a direction parallel to the surface of the first redistribution layer. The capacitor is electrically connected with the first wiring, and includes an insulation layer, a first electrode layer, a dielectric layer, and a second electrode layer stacked in a sequential order in a direction perpendicular to the first redistribution layer. The semiconductor package also includes a post disposed on the capacitor in a direction perpendicular to the surface of the first redistribution layer and electrically connected to the first redistribution layer.

Additionally or alternatively, according some example embodiments, a semiconductor package may include a first redistribution layer having first wiring, a semiconductor die on a surface of the first redistribution layer, a capacitor on the surface of the first redistribution layer and spaced apart from the semiconductor die in a direction parallel to the surface of the first redistribution layer. The capacitor may be electrically connected to the first wiring, and may include an insulation layer, a first electrode layer, a dielectric layer, and a second electrode layer that may be stacked in sequential order in a direction perpendicular to the first redistribution layer. The semiconductor package also includes a post on the capacitor and extending in a direction perpendicular to the surface of the first redistribution layer and electrically connected to the first redistribution layer. The first electrode layer is configured to have a first polarity, the second electrode layer is configured to have a second polarity, and the post includes a first post configured to have the first polarity, and a second post configured to have the second polarity. The semiconductor package further includes a first via configured to have the first polarity and configured to connect the first post and the first redistribution layer, and a second via configured to have the second polarity and configured to connect the second post and the first redistribution layer.

### BRIEF DESCRIPTION OF THE DRAWINGS

Example embodiments will be more clearly understood from the following detailed description taken in conjunction with the accompanying drawings in which:

FIG. 1 illustrates a cross section of a semiconductor package, according to some example embodiments.

FIG. 2 is a cross sectional view of the semiconductor package of FIG. 1 taken along line I-I of FIG. 1 with the molding member removed.

FIG. 3 illustrates an enlarged part A of FIG. 1, according to some example embodiments.

FIGS. 4, 5, 6, and 7 illustrate operations in a process of manufacturing a capacitor module, according to some example embodiments.

FIG. 8 illustrates a cross section of a semiconductor package, according to some example embodiments.

FIG. 9 illustrates an enlarged part D of FIG. 8, according to some example embodiments.

FIGS. 10, 11, 12, and 13 illustrates operations in a process of fabricating a capacitor included in a semiconductor package, according to some example embodiments.

FIG. 14 illustrates a post included in a semiconductor package, according to some example embodiments.

FIG. 15 illustrates a semiconductor stack package, according to some example embodiments.

### DETAILED DESCRIPTION

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed.

Terms including an ordinal number such as “first” or “second” used in the present specification and claims may be used to distinguish elements. Such an ordinal number is used to contextually distinguish identical or similar elements from each other. Meanings of the terms may not be limited by use of the ordinal number. For example, a use order, a disposition order, or the like of elements with such an ordinal number may not be limitedly construed by the number. As required, ordinal numbers may be substituted with each other.

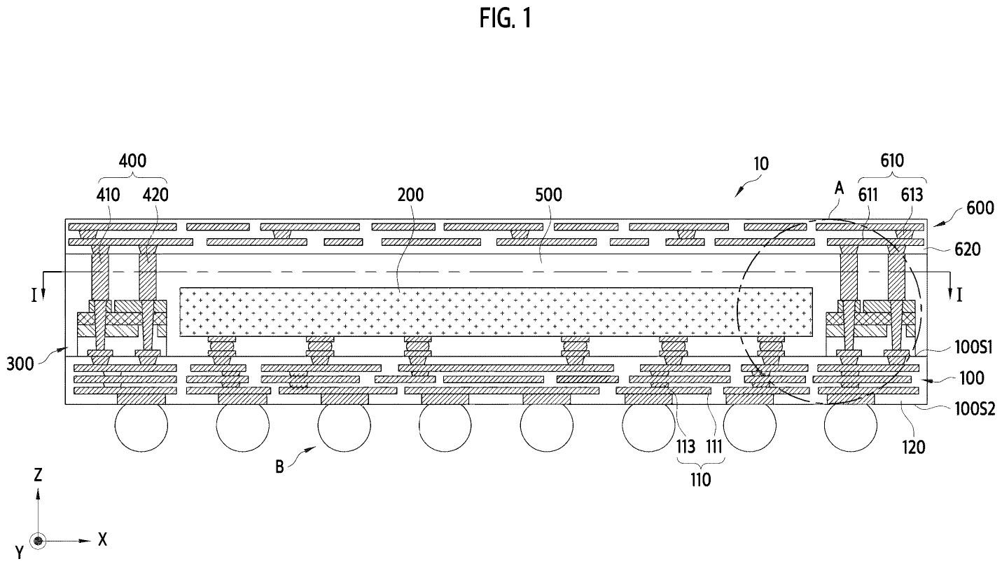

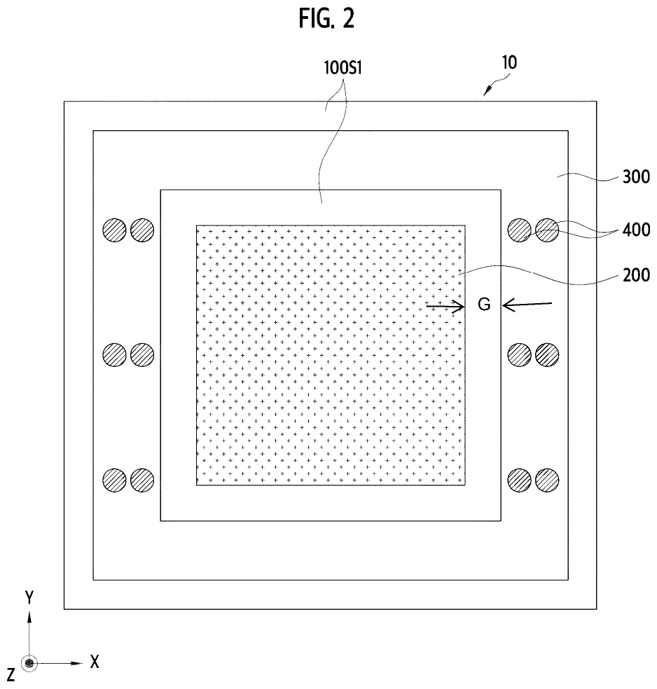

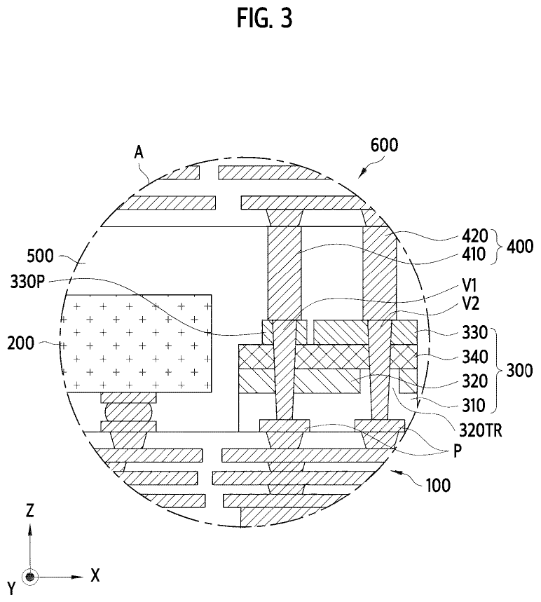

FIG. 1 illustrates a cross section of a semiconductor package, according to some example embodiments. FIG. 2 is a cross sectional view of the semiconductor package of FIG. 1 taken along line I-I of FIG. 1 with the molding member removed. FIG. 3 illustrates an enlarged part A of FIG. 1, according to some example embodiments.

Referring to FIGS. 1 through 3, a semiconductor package 10 may include a first redistribution layer 100, a semiconductor die 200, a capacitor 300, and a post 400.

The first redistribution layer 100, according to some example embodiments, may include first wiring 110. The first redistribution layer 100 may include an insulation layer 120. The first wiring 110 may be disposed (or otherwise arranged) in the insulation layer 120. A plurality of insulation layers 120 including the insulation layer 120 may be stacked. The first wiring 110 may include a plurality of vias 113 for vertically connecting a plurality of wiring patterns 111 to each other. The first wiring 110 may be or include a conductive material. For example, the first wiring 110 may be or include gold (Au), silver (Ag), copper (Cu), nickel (Ni), or aluminum (Al).

The semiconductor die 200, according to some example embodiments, may be a logic chip disposed (or arranged) on a surface 100S1 of the first redistribution layer 100. For example, the semiconductor die 200 may be an application processor (AP) chip. However, the semiconductor die 200 is not limited to the AP chip and, in some example embodiments, the semiconductor die 200 may be a central processing unit (CPU) chip, a graphic processing unit (GPU) chip, a memory chip, or the like.

The capacitor 300, according to some example embodiments, may be disposed (or arranged) on the surface 100S1 of the first redistribution layer 100. The capacitor 300 may be disposed spaced apart from the semiconductor die 200 in a direction parallel to the surface 100S1 of the first redistribution layer 100 (e.g., any direction on a plane parallel to an XY-plane). The capacitor 300 may be electrically connected to the first wiring 110. The capacitor 300 may include an insulation layer 310, a first electrode layer 320, a second electrode layer 330, and a dielectric layer 340. The insulation layer 310, the first electrode layer 320, the dielectric layer 340, and the second electrode layer 330 may be stacked in sequential order in a direction perpendicular to the first redistribution layer 100 (e.g., along the Z-axis). In some example embodiments, the capacitor 300 may be a thin film capacitor. The first electrode layer 320 may have a first polarity during operation. The second electrode layer 330 may have a second polarity during operation.

The insulation layer 310, according to some example embodiments, may be or include silicon dioxide (SiO₂) or silicon nitride (SiNₓ). However, in some example embodiments, the insulation layer 310 may be or include a photoimageable dielectric. In some example embodiments, the insulation layer 310 may include a photoimageable polymer. The photoimageable polymer may be or include at least one of photoimageable polyimide, polybenzoxazole, a phenol-based polymer, a benzocyclobutene-based polymer or the like. In some example embodiments, the insulation layer 310 may include a silicon oxide film, a silicon nitride film, a silicon oxynitride film, a combination thereof, or the like.

The first electrode layer 320 and the second electrode layer 330, according to some example embodiments, may be spaced apart in the direction perpendicular to the first redistribution layer 100 (e.g., along the Z-axis) with the dielectric layer 340 therebetween. The first electrode 320 may be disposed on the insulation layer 310. The first electrode 320 may be disposed below the dielectric layer 340. The second electrode layer 330 may be disposed on the dielectric layer 340.

The first electrode layer 320 and the second electrode layer 330, according to some example embodiments, may be formed as one (or single) layer to have a predetermined pattern. The first electrode layer 320 and the second electrode layer 330 may be or include a conductive material. The conductive material may be copper (Cu), aluminum (Al), gold (Au), silver (Ag), platinum (Pt), iridium (Ir), ruthenium (Ru), or the like. However, conductive materials may also include other materials.

The dielectric layer 340, according to some example embodiments, may be disposed between the first electrode layer 320 and the second electrode layer 330. The dielectric layer 340 may be or include at least one of silicon dioxide (SiO₂), silicon nitride (SiNₓ), and alumina (Al₂O₃) or a combination thereof. However, the dielectric layer 340 may also include other materials.

The insulation layer 310, the first electrode layer 320, the second electrode layer 330, and the dielectric layer 340, according to some example embodiments, may be formed by a deposition process.

The post 400, according to some example embodiments, may be disposed (or arranged) on the capacitor 300 in a direction perpendicular to the surface 100S1 of the first redistribution layer 100 (e.g., along the Z-axis). The post 400 may be electrically connected to the capacitor 300. The post 400 may be electrically connected to the first redistribution layer 100. The post 400 may include a first post 410 having the first polarity during operation. The post 400 may include a second post 420 having the second polarity during operation.

The semiconductor package 10, according to some example embodiments, may further include a molding member 500, a second redistribution layer 600, and a bump B.

The molding member 500, according to some example embodiments, may be disposed on the surface 100S1 of the first redistribution layer 100. The molding member 500 may cover the surface 100S1 of the first redistribution layer 100. The molding member 500 may surround at least a portion of the semiconductor die 200, the capacitor 300, and the post 400. In some example embodiments, and as illustrated, the molding member 500 may enclose or encapsulate the semiconductor die 200, the capacitor 300, and the post 400 so that the semiconductor die 200, the capacitor 300, and the post 400 are not exposed outside of the molding member 500.

The molding member 500 according to some example embodiments may be or include a thermosetting resin, a thermoplastic resin, an ultraviolet (UV)-curing resin, or a combination thereof. For example, the molding member 500 may be or include an epoxy resin, a silicone resin, or a combination thereof. In some example embodiments, the molding member 500 may be or include an epoxy mold compound (EMC).

The second redistribution layer 600, according to some example embodiments, may include second wiring 610. The second wiring 610 may include a plurality of vias 613 for vertically connecting a plurality of wiring patterns 611 to each other. The second redistribution layer 600 may be disposed on the post 400 and a surface of the molding member 500. The second redistribution layer 600 may be electrically connected with the post 400 and the first wiring 110. The second redistribution layer 600 may be similar in some respects to the first redistribution layer 100 and may be best understood with reference thereto and a description thereof is omitted for the sake of brevity.

The bump B, according to some example embodiments, may be disposed on a surface 100S2 of the first redistribution layer 100 opposite the surface 100S1. The bump B may include a solder ball or a solder bump. For example, the bump B may have a spherical shape or an elliptically spherical shape, but may have other shapes depending on application and/or design. The number of bumps B, an interval between the bumps B, an arrangement of the bump B, or a shape of the bump B, or the like are not limited in any particular way and may vary depending on application and/design. The bump B may be or include, for example, tin (Sn), indium (In), bismuth (Bi), antimony (Sb), copper (Cu), silver (Ag), zinc (Zn), lead (Pb), a combination thereof, and the like. However, the bump may also include other materials.

The semiconductor package 10, according to some example embodiments, may more efficiently utilize space by arranging the capacitor 300 and the semiconductor die 200 on the same surface 100S1 of the first redistribution layer 100. As a result, the semiconductor package 10 may be relatively thinner. The semiconductor package 10, according to some example embodiments, includes the capacitor 300 on the surface 100S1 of the first redistribution layer 100 and the bump B on a surface 100S2 of the first redistribution layer 100 opposite the surface 100S1.

Hereinafter, a process of manufacturing a capacitor module 300′, according to some example embodiments, is described. As discussed further below, the capacitor module 300′ may be used to fabricate the capacitor 300.

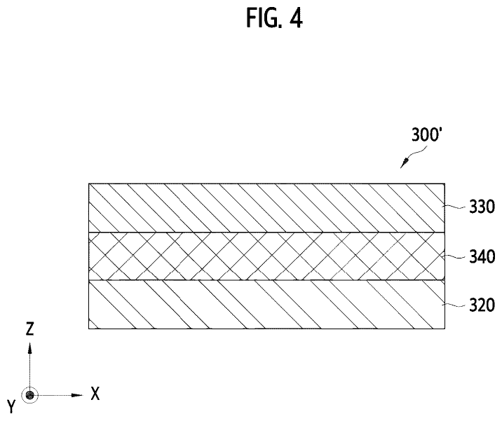

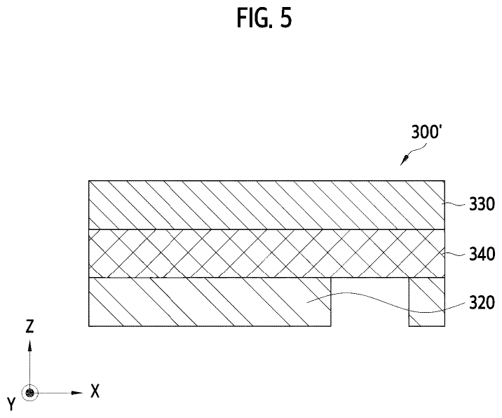

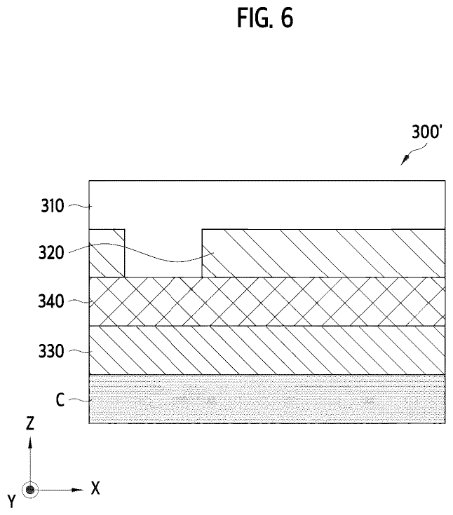

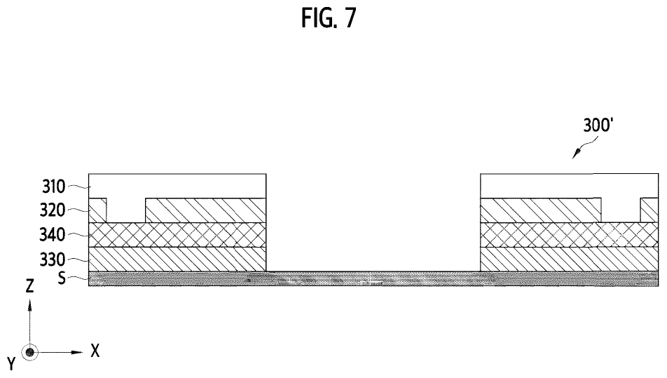

FIGS. 4 through 7 illustrate operations in a process of manufacturing a capacitor module, according to some example embodiments. FIG. 4 illustrates the capacitor module 300′ in which the first electrode 320, the second electrode 330, and the dielectric layer 340 are stacked. FIG. 5 illustrates a patterning operation performed for the first electrode layer 320. FIG. 6 illustrates the insulation layer 310 stacked on the capacitor module 300′ which is on a film C. FIG. 7 illustrates a protective sticker S on the second electrode 330 in order to transfer a completed capacitor module 300′.

Referring to FIGS. 4 through 7, the capacitor 300 may be manufactured using the capacitor module 300′ which may be produced separately from the semiconductor package 10. In some example embodiments, the capacitor module 300′ may be produced before manufacturing the semiconductor package 10.

Referring to FIG. 4, the capacitor module 300′ may include the first electrode layer 320, the second electrode layer 330, and the dielectric layer 340. The first electrode layer 320, the dielectric layer 340, and the second electrode layer 330 may be stacked in sequential order from bottom to top (in a positive direction of a Z-axis) by a sputtering and/or deposition process.

Referring to FIG. 5, the first electrode layer 320 may be patterned according to a semiconductor package design. The first electrode layer 320 may be patterned by an etching process.

Referring to FIG. 6, after patterning, the capacitor module 300′ may be flipped so that the first electrode layer 320 is positioned at the top (in the positive direction of the Z-axis) and the capacitor module 300′ may be placed or arranged on the film C. The film C may protect the second electrode layer 330 during an operation in which the insulation layer 310 may be stacked on an upper surface of the first electrode layer 320. The film C may be removed after the stacking operation. In some example embodiments, the insulation layer 310 may be stacked by the deposition process.

The capacitor module 300′ on which the insulation layer 310 is stacked may be cut (or diced) depending on a capacity and/or a structure of the capacitor 300 used in the semiconductor package 10. For example, referring to FIGS. 1, 2, and 7, the capacitor 300 may be shaped as a rectangular annulus having a rectangular opening in a middle or central portion thereof. The rectangular opening may be shaped and/or sized (or otherwise configured) such that the semiconductor die 200 may be accommodated in the opening and that the capacitor 300 is spaced apart from the semiconductor die 200. In other words, a space or gap G (FIG. 2) may be defined between an outer peripheral edge of the semiconductor die 200 and the inner edge of the capacitor 300. FIG. 7 illustrates a cross section of the capacitor module 300′ shaped as a rectangular annulus and having a rectangular opening in the central portion thereof. In the cut capacitor module 300′, the protective sticker S may be attached (e.g., removably attached) to the second electrode layer 330 for transferring a completed capacitor module 300′. The protective sticker S may be removed after the transfer and/or after the semiconductor package 10 is manufactured.

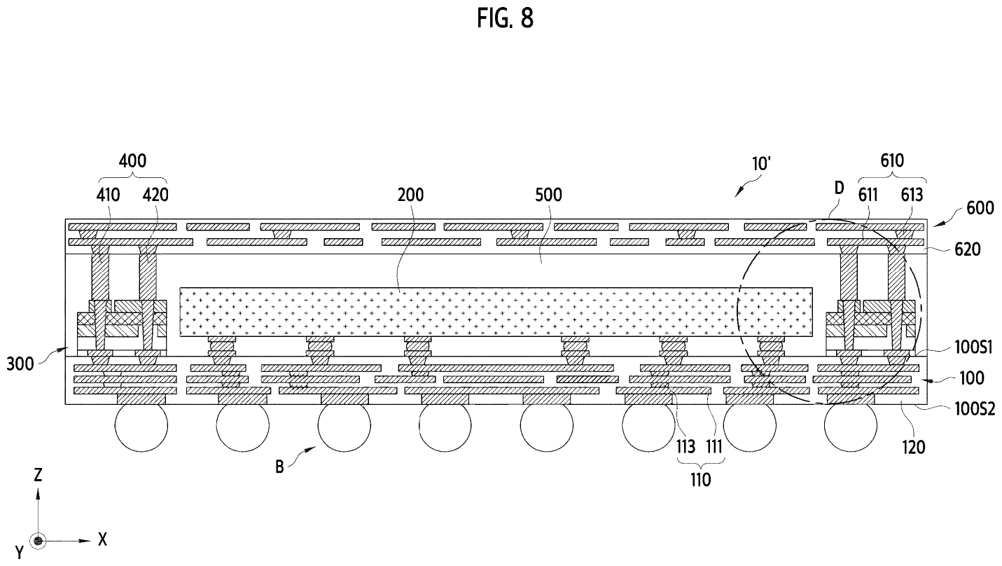

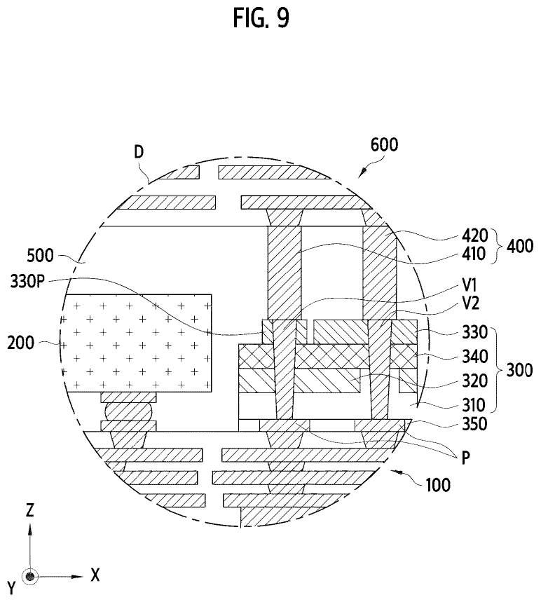

FIG. 8 illustrates a cross section of a semiconductor package, according to some example embodiments. FIG. 9 illustrates an enlarged part D of FIG. 8, according to some example embodiments.

Referring to FIGS. 8 and 9, a semiconductor package 10′, according to some example embodiments, may include an additional insulation layer 350.

The additional insulation layer 350 for the semiconductor package 10′ may be arranged between the capacitor 300 and the first redistribution layer 100. As illustrated in FIG. 9, the additional insulation layer 350 may vertically separate the capacitor 300 and the first redistribution layer 100. To position or arrange the capacitor module 300′ on the first redistribution layer 100, the additional insulation layer 350 may be stacked on the first redistribution layer 100 before the capacitor module 300′ is positioned. In some example embodiments, the additional insulation layer 350 may be formed by a deposition process.

A process of fabricating the capacitor 300 from the capacitor module 300′ using processes such as patterning and/or via formation is discussed below. The capacitor 300 may be fabricated after the capacitor module 300′ is positioned on the first redistribution layer 100.

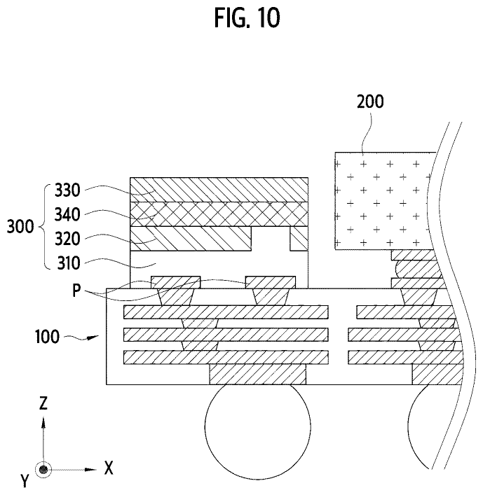

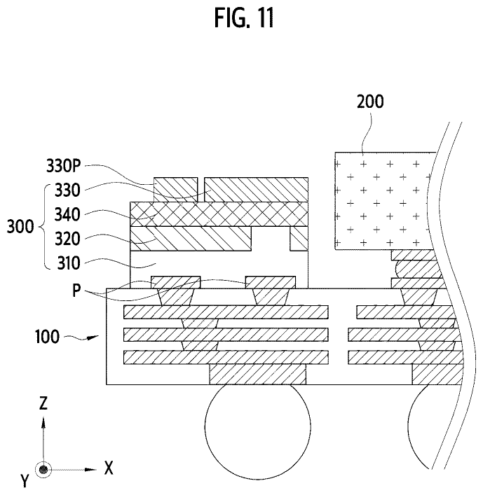

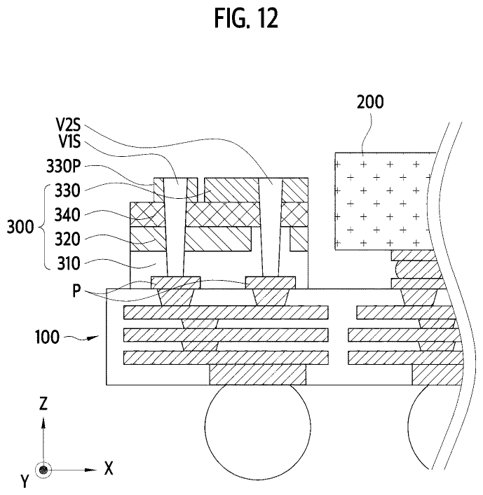

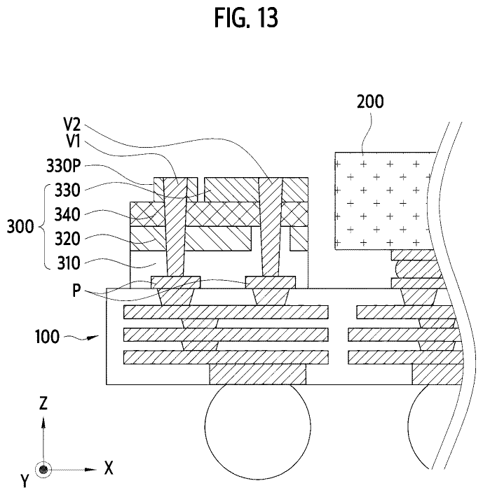

FIGS. 10 through 13 illustrate operations in a process of fabricating a capacitor included in a semiconductor package, according to some example embodiments. FIG. 10 illustrates the capacitor 300 positioned on the first redistribution layer 100. FIG. 11 illustrates the second electrode layer 330 of the capacitor 300 after a patterning process. FIG. 12 illustrates etching process is performed to form spaces V1S and V2S formed using an etching process. FIG. 13 illustrates vias V1 and V2 formed using a plating process.

Forming the capacitor 300 may include patterning the second electrode layer 330 of the capacitor module 300′ positioned on the first redistribution layer 100. After the patterning process, the capacitor 300 may include the second electrode layer 330 configured to have a second polarity during operation and a second electrode layer pad 330P configured to have a first polarity during operation. As discussed below, a first via V1 may be connected to the second electrode layer pad 330P. The second electrode layer 330 may be patterned depending on design of the semiconductor package 10. Referring to FIG. 3, with continued reference to FIGS. 10-13, the capacitor 300 may include the first electrode layer 320 having the first polarity (during operation) and a first electrode layer trench 320TR formed by patterning in the first electrode layer 320. A second via V2 (described below) may be in the first electrode layer trench 320TR and may be surrounded by the insulation layer 310. After patterning the second electrode 330, an etching process may be performed to form the a first via V1 and a second via V2. Via openings V1S and V2S which respectively correspond to openings in which the first and second vias V1 and V2 may initially be formed by an etching process. The first and second vias V1 and V2 may be formed by filling the via openings V1S and V2S with a conductive material using a plating process. Each of the first and second vias V1 and V2 may be electrically connected to the first redistribution layer 100 via respective connection pads P formed on the surface 100S1 of the first redistribution layer 100. The first via V1 may have the first polarity (during operation) and may connect (e.g., electrically connect) the first post 410 and the first redistribution layer 100 via the connection pad P. The second via V2 may have the second polarity (during operation) and may connect (e.g., electrically connect) the second post 420 and the first redistribution layer 100 via the connection pad P. The first via V1 and the second via V2 may be electrically insulated from each other. At least a portion of the first via V1 may be connected to the second electrode layer pad 330P. At least a portion of the second electrode layer pad 330P may be surrounded by the molding member 500. At least a portion of the second via V2 may be surrounded by the insulation layer 310. It will be understood that the arrangement of the first via V1 and the second via V2 and the numbers of first vias V1 and second vias V2 may vary depending on a design and/or application of the semiconductor package 10.

Referring to FIG. 1, with continued reference to FIGS. 10-13, the first post 410 and the second post 420, which are electrically connected with the first via V1 and the second via V2, respectively, may be fabricated after formation of the first and second vias V1 and V2. In some example embodiments, the first post 410 and the second post 420 may be fabricated using a photolithography process and/or a plating process.

A plating process for fabricating the post 400 is described below.

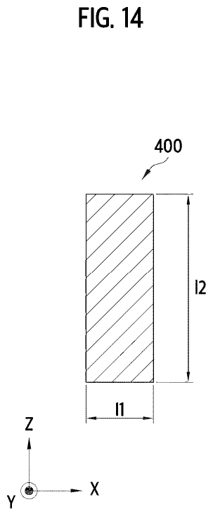

FIG. 14 illustrates a post included in a semiconductor package 10, according to some example embodiments.

Referring to FIG. 14, and with reference to FIG. 1, a height 12 of the post 400 in a direction perpendicular to the surface 100S1 of the first redistribution layer 100 (e.g., a direction parallel to a Z-axis) may be smaller than three times or about three times a width of the post 400 in a direction parallel to the first redistribution layer 100 (e.g., any direction on a surface parallel to an XY-plane). A proportion of a length of the post 400 may be smaller in a width-to-length aspect ratio of the post 400 when compared to a case in which the aspect ratio is 1:3.

Such a configuration may increase, improve, and/or maximized the strength of the post 400 by limiting and/or preventing voids in an inner space (or interior) of the post 400. In some example embodiments, the post 400 may be formed using a plating process. The post 400 may be formed by initially forming an opening by a photolithography process and then filling the opening using the plating process. When an aspect ratio of a width 11 to the height 12 of the post in increased, the opening may not be completely filled in the plating process, and an interior or inner space of the post may include voids. Accordingly, the strength of the post 400 may be relatively lower, and an overall strength of the semiconductor package may also decrease. The fabrication processes, according to some example embodiments, may improve strength of the semiconductor package by positioning the capacitor 300 below the post 400 (in a negative direction of the Z-axis) to decrease and/or minimize the width-to-length aspect ratio of the post 400. Particularly, an aspect ratio of the first post 410 may be decreased and/or minimized by forming the first via V1 in the layer including the second electrode layer pad 330P.

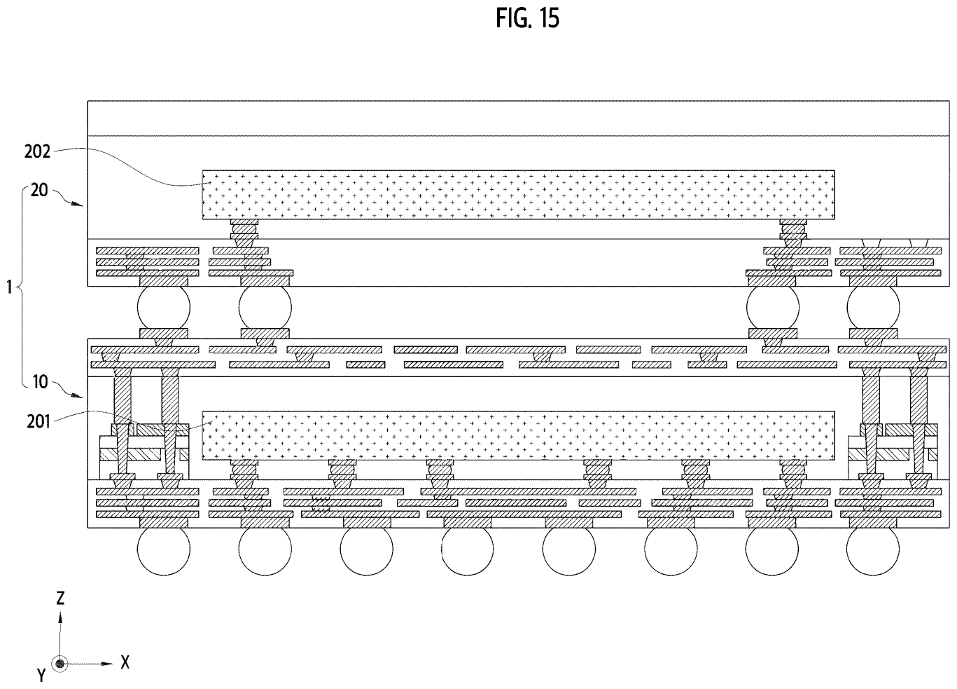

FIG. 15 illustrates a semiconductor stack package 1, according to some example embodiments.

Referring to FIG. 15, the semiconductor stack package 1 may be a stacked structure including the semiconductor package 10 and a semiconductor package 20 stacked on the semiconductor package 10. The semiconductor package 10 and the semiconductor package 20 may be electrically connected. In some example embodiments, a semiconductor die 201 of the semiconductor package 10 may be or include an application processor (AP) chip, and a semiconductor die 202 of the semiconductor package 20 may be or include a memory chip.

The example embodiments have been described with reference to the accompanying drawings above. However, the present disclosure is not limited to the above example embodiments and may be manufactured in various forms different from each other. Those skilled in the art to which the present disclosure belongs may understand that other embodiments may be implemented without changing the technical spirit or the required characteristics of the present disclosure. Therefore, in all aspects, the above-described example embodiments should be understood as mere examples and not as being limitative.

What is claimed is:

1. A semiconductor package comprising:
a first redistribution layer including a first wiring;
a semiconductor die on a first surface of the first redistribution layer;
a capacitor on the first surface of the first redistribution layer and spaced apart from the semiconductor die in a direction parallel to the first surface of the first redistribution layer, the capacitor being electrically connected to the first wiring, and including an insulation layer, a first electrode layer, a dielectric layer, and a second electrode layer that are stacked in a sequential order in a direction perpendicular to the first redistribution layer; and
a post on the capacitor, extending in a direction perpendicular to the first surface of the first redistribution layer, and electrically connected to the first redistribution layer.

2. The semiconductor package of claim 1, wherein
the first electrode layer is configured to have a first polarity,
the second electrode layer is configured to have a second polarity, and
the post includes,
a first post configured to have the first polarity, and
a second post configured to have the second polarity.

3. The semiconductor package of claim 2, further comprising a first via configured to have the first polarity and configured to connect the first post and the first redistribution layer.

4. The semiconductor package of claim 2, further comprising a second via configured to have the second polarity and configured to connect the second post and the first redistribution layer.

5. The semiconductor package of claim 4, wherein at least a portion of the second via is surrounded by the insulation layer.

6. The semiconductor package of claim 1, further comprising an additional insulation layer between the capacitor and the first redistribution layer.

7. The semiconductor package of claim 1, further comprising a second redistribution layer on the post,
wherein the second redistribution layer includes a second wiring electrically connected to the post.

8. The semiconductor package of claim 1, wherein a height of the post in the direction perpendicular to the first surface of the first redistribution layer is less than three times a width of the post in a direction parallel to the first redistribution layer.

9. The semiconductor package of claim 8, wherein the post includes copper.

10. The semiconductor package of claim 1, further comprising a bump on a second surface of the first redistribution layer, the bump including a conductive material.

11. The semiconductor package of claim 1, further comprising a molding member configured to:
enclose the semiconductor die, the capacitor, and the post and to cover the first surface of the first redistribution layer; and
fill a space between the semiconductor die, the capacitor, and the post.

12. A semiconductor stack package comprising the semiconductor package of claim 1 and further including another semiconductor package stacked on the semiconductor package.

13. A semiconductor package comprising:
a first redistribution layer including a first wiring;
a semiconductor die on a first surface of the first redistribution layer;
a capacitor on the first surface of the first redistribution layer and spaced apart from the semiconductor die in a direction parallel to the first surface of the first redistribution layer, the capacitor being electrically connected to the first wiring, and the capacitor including a first insulation layer, a first electrode layer, a dielectric layer, and a second electrode layer that are stacked in a sequential order in a direction perpendicular to the first redistribution layer; and
a post on the capacitor and extending in a direction perpendicular to the first surface of the first redistribution layer and electrically connected to the first redistribution layer, wherein
the first electrode layer is configured to have a first polarity,
the second electrode layer is configured to have a second polarity,
the post includes
a first post configured to have the first polarity, and
a second post configured to have the second polarity, and
the semiconductor package further includes,
a first via configured to have the first polarity and configured to connect the first post and the first redistribution layer, and
a second via configured to have the second polarity and configured to connect the second post and the first redistribution layer.

14. The semiconductor package of claim 13, wherein at least a portion of the second via is surrounded by the first insulation layer.

15. The semiconductor package of claim 13, further comprising a second insulation layer between the capacitor and the first redistribution layer.

16. The semiconductor package of claim 13, further comprising a second redistribution layer on the post,
wherein the second redistribution layer includes second wiring that is configured to electrically connect with the post.

17. The semiconductor package of claim 13, wherein a height of the post in the direction perpendicular to the first surface of the first redistribution layer is less than three times a width of the post in a direction parallel to the first redistribution layer.

18. The semiconductor package of claim 17, wherein the post includes copper.

19. The semiconductor package of claim 13, further comprising a molding member configured to:
enclose the semiconductor die, the capacitor, and the post and to cover the first surface of the first redistribution layer; and
fill a space between the semiconductor die, the capacitor, and the post.

20. The semiconductor package of claim 13, further comprising a bump on a second surface of the first redistribution layer, the bump including a conductive material.
